(19) United States
(12) Patent Application Publication
(10) Pub. No.: US 2022/0311215 A1
(43) Pub. Date: Sep. 29, 2022

(54) QUANTUM CASCADE LASER

(71) Applicant: HAMAMATSU PHOTONICS K.K., Hamamatsu-shi (JP)

(72) Inventors: Akio ITO, Hamamatsu-shi (JP); Kazuue FUJITA, Hamamatsu-shi (JP); Shohei HAYASHI, Hamamatsu-shi (JP); Tatsuo DOUGAKIUCHI, Hamamatsu-shi (JP)

(73) Assignee: HAMAMATSU PHOTONICS K.K., Hamamatsu-shi (JP)

(21) Appl. No.: 17/701,899

(22) Filed: Mar. 23, 2022

(30) Foreign Application Priority Data
Mar. 29, 2021 (JP) 2021-055632

(51) Int. Cl. H01S 5/34; H01S 5/026

(52) U.S. Cl. CPC H01S 5/3401; H01S 5/026

(57) ABSTRACT

A quantum cascade laser includes a semiconductor substrate, an optical waveguide formed on a first surface of the semiconductor substrate, and a temperature adjusting member. The optical waveguide includes a first region and a second region located on one side with respect to the first region in the optical waveguide direction of the optical waveguide. The first region generates a first light having a first wavelength, and the second region generates a second light having a second wavelength. The optical waveguide generates an output light having a frequency corresponding to a difference between the first wavelength and the second wavelength by difference-frequency generation. A recess for suppressing heat transfer between the first region and the second region is formed at a second surface of the semiconductor substrate. The temperature adjusting member includes a first temperature adjusting member for adjusting the temperature of the second region.

### TECHNICAL FIELD

One aspect of the present disclosure relates to a quantum cascade laser.

### BACKGROUND

As a quantum cascade laser, there is known a terahertz difference-frequency quantum cascade laser (or terahertz nonlinear quantum cascade laser) that includes an optical waveguide having a first region for generating light having a first wavelength and a second region for generating light having a second wavelength and outputs light having a difference-frequency in a terahertz band according to a difference between the first wavelength and the second wavelength by difference-frequency generation (refer to, for example, International Publication WO 2015/163965).

### SUMMARY

In terahertz band spectroscopic measurement, which is expected as one of application fields of a terahertz nonlinear quantum cascade laser as described above, it is required that a frequency of an output light can be tuned. However, when the difference-frequency generation is used, even if the applied current or the temperature is changed, each of the first wavelength and the second wavelength is similarly shifted, and the frequency of the output light cannot be changed. On the other hand, in the quantum cascade laser described in International Publication WO 2015/163965, the frequency of the terahertz output light is changed with heating by applying a DC bias to the second region. However, there is a concern that the temperature of the first region is increased due to the heat transfer from the second region to the first region, and the oscillation threshold value in the first region is increased.

One aspect of the present disclosure is to provide a quantum cascade laser capable of suppressing an increase in the oscillation threshold value while tuning the frequency of the output light.

According to one aspect of the present disclosure, a quantum cascade laser includes: a semiconductor substrate including a first surface and a second surface opposite to the first surface; an optical waveguide including an active layer having a quantum cascade structure and a pair of clad layers interposing the active layer therebetween, the optical waveguide being formed on the first surface of the semiconductor substrate and being provided with a diffraction grating structure; and a temperature adjusting member, wherein the optical waveguide includes a first region and a second region located on one side with respect to the first region in the optical waveguide direction of the optical waveguide, the first region generates a first light having a first wavelength and the second region generates a second light having a second wavelength, and the optical waveguide generates an output light having a frequency corresponding to a difference between the first wavelength and the second wavelength by difference-frequency generation, wherein a recess for suppressing heat transfer between the first region and the second region is formed at the second surface of the semiconductor substrate, and wherein the temperature adjusting member includes a first temperature adjusting member for adjusting the temperature of the second region.

In the quantum cascade laser, the temperature adjusting member includes the first temperature adjusting member for adjusting the temperature of the second region. Accordingly, the temperature of the second region can be adjusted by using the first temperature adjusting member, and as a result, a temperature difference is formed between the first region and the second region, so that the frequency of the output light can be changed. Further, the recess for suppressing heat transfer between the first region and the second region is formed at the second surface of the semiconductor substrate. Accordingly, the heat transfer from the second region to the first region can be suppressed, and the increase in the oscillation threshold value in the first region caused by the heat transfer can be suppressed. Therefore, according to the quantum cascade laser, the increase in the oscillation threshold value can be suppressed while the frequency of the output light can be tuned.

The recess may be arranged so as to overlap a boundary between the first region and the second region when viewed from a direction perpendicular to the second surface. In this case, the heat transfer from the second region to the first region can be effectively suppressed.

The recess may be arranged so as to overlap a region between a boundary between the first region and the second region and a straight line bisecting the second region into one side and the other side in the optical waveguide direction when viewed from a direction perpendicular to the second surface. In this case, the heat transfer from the second region to the first region can be effectively suppressed.

The recess may be a groove. In this case, the heat transfer from the second region to the first region can be effectively suppressed.

A plurality of holes each of which forms recess may be formed on the second surface. In this case, the heat transfer from the second region to the first region can be effectively suppressed. Further, since the semiconductor substrate exists between the plurality of holes, the mechanical strength can be secured.

The length of the recess in the optical waveguide direction may be 100 μm or more and 500 μm or less. In this case, the heat transfer from the second region to the first region can be effectively suppressed.

A depth of the recess may be ½ or more of a distance between a bottom surface of the recess and the first surface. In this case, the heat transfer from the second region to the first region can be effectively suppressed.

The semiconductor substrate may include a first portion overlapping the first region and a second portion overlapping the second region when viewed from a direction perpendicular to the second surface, and the heat capacity of the first portion may be larger than the heat capacity of the second portion. In this case, even if heat is transferred from the second region to the first region, an increase in the temperature of the first region due to the heat can be suppressed, as a result, an increase in the oscillation threshold value can be suppressed.

According to one aspect of the present disclosure, a quantum cascade laser includes: a semiconductor substrate including a first surface and a second surface opposite to the first surface; an optical waveguide including an active layer having a quantum cascade structure and a pair of clad layers interposing the active layer therebetween, the optical waveguide being formed on the first surface of the semiconductor substrate and being provided with a diffraction grating structure; and a temperature adjusting member, wherein the optical waveguide includes a first region and a second region located on one side with respect to the first region in the optical waveguide direction of the optical waveguide, the first region generates a first light having a first wavelength and the second region generates a second light having a second wavelength, and the optical waveguide generates an output light having a frequency corresponding to a difference between the first wavelength and the second wavelength by difference-frequency generation, wherein the semiconductor substrate includes a first portion overlapping the first region and a second portion overlapping the second region when viewed from a direction perpendicular to the second surface, wherein heat capacity of the first portion is larger than heat capacity of the second portion, and wherein the temperature adjusting member includes a first temperature adjusting member for adjusting the temperature of the second region.

In the quantum cascade laser, the temperature adjusting member includes the first temperature adjusting member for adjusting the temperature of the second region. Accordingly, the temperature of the second region can be adjusted by using the first temperature adjusting member, and as a result, a temperature difference is formed between the first region and the second region, so that the frequency of the output light can be changed. Further, in the semiconductor substrate, the heat capacity of the first portion is larger than the heat capacity of the second portion. Accordingly, even if heat is transferred from the second region to the first region, an increase in the temperature of the first region due to the heat can be suppressed, and as a result, an increase in the oscillation threshold value can be suppressed. Therefore, according to this quantum cascade laser, the increase in the oscillation threshold value can be suppressed while the frequency of the output light can be tuned.

The thickness of the first portion may be larger than the thickness of the second portion. In this case, the heat capacity of the first portion can be larger than the heat capacity of the second portion, and the increase in the oscillation threshold value can be suppressed.

The length of the first portion in the optical waveguide direction may be larger than the length of the second portion in the optical waveguide direction. In this case, the heat capacity of the first portion can be larger than the heat capacity of the second portion, and the increase in the oscillation threshold value can be suppressed.

A width of the first portion may be larger than a width of the second portion. In this case, the heat capacity of the first portion can be larger than the heat capacity of the second portion, and the increase in the oscillation threshold value can be suppressed.

The first temperature adjusting member may be arranged on the second surface of the semiconductor substrate. In this case, the temperature of the second region can be adjusted via the semiconductor substrate having a relatively large heat capacity, and a large temperature difference can be formed between the first region and the second region. In particular, when a recess for suppressing heat transfer between the first region and the second region is formed at the second surface of the semiconductor substrate, the temperature is adjusted from the second surface side by the first temperature adjusting member and the recess is formed at the second surface, and thus, a large temperature difference can be formed between the first region and the second region.

The first temperature adjusting member may be arranged on a surface of the optical waveguide opposite to the semiconductor substrate. In this case, the first temperature adjusting member can be close to the active layer, and the temperature of the second region can be adjusted with high accuracy.

The temperature adjusting member may further include a second temperature adjusting member for adjusting the temperature of the first region. In this case, since the temperature of the second region can be adjusted by using the first temperature adjusting member in a state where the temperature of the first region is maintained constant by using, for example, the second temperature adjusting member, the steady state of the laser can be easily maintained, and as a result, operation under a high heat load such as continuous driving can be easily performed.

The second temperature adjusting member may be arranged on the second surface of the semiconductor substrate. In this case, the temperature of the first region can be adjusted via the semiconductor substrate having a relatively large heat capacity, and a large temperature difference can be formed between the first region and the second region. In particular, when a recess for suppressing heat transfer between the first region and the second region is formed on the second surface of the semiconductor substrate, the temperature is adjusted from the second surface side by the second temperature adjusting member and the recess is formed on the second surface, and thus a large temperature difference can be formed between the first region and the second region.

The second temperature adjusting member may be arranged on a surface of the optical waveguide opposite to the semiconductor substrate. In this case, the second temperature adjusting member can be close to the active layer, and the temperature of the first region can be adjusted with high accuracy.

The first temperature adjusting member may be a Peltier element. The second temperature adjusting member may be a Peltier element. In this case, the temperatures of the first region and the second region can be appropriately adjusted.

The diffraction grating structure may include a first diffraction grating structure formed in the first region and a second diffraction grating structure formed in the second region, the first diffraction grating structure may include a plurality of grooves arranged at a pitch corresponding to the first wavelength, and the second diffraction grating structure may include a plurality of grooves arranged at a pitch corresponding to the second wavelength. In this case, the first region can generate the first light having the first wavelength, and the second region can generate the second light having the second wavelength.

According to one aspect of the present disclosure, it is possible to provide a quantum cascade laser capable of suppressing an increase in the oscillation threshold value while tuning the frequency of the output light.

### BRIEF DESCRIPTION OF THE DRAWINGS

FIG. 1 is a cross-sectional view of a quantum cascade laser according to an embodiment.

FIG. 2 is a cross-sectional view illustrating a structure of the quantum cascade laser.

FIG. 3 is a diagram illustrating a structure of a unit laminate structure in an active layer.

FIG. 4A is a graph illustrating changes in a first wavelength and a second wavelength when the applied current is changed, and FIG. 4B is a graph illustrating changes in the first wavelength and the second wavelength when the temperature is changed.

FIG. 5 is a cross-sectional view of a quantum cascade laser according to Modified Example 1.

FIG. 6 is a cross-sectional view of a quantum cascade laser according to Modified Example 2.

FIG. 7 is a cross-sectional view of a quantum cascade laser according to Modified Example 3.

FIG. 8 is a cross-sectional view of a quantum cascade laser according to Modified Example 4.

FIG. 9A is a cross-sectional view of a quantum cascade laser according to Modified Example 5, and FIG. 9B is a plan view of the quantum cascade laser according to Modified Example 5.

### DETAILED DESCRIPTION

Hereinafter, one embodiment of the present disclosure will be described in detail with reference to the drawings. In the following description, the same or equivalent elements will be denoted by the same reference numerals, and duplicate description will be omitted.

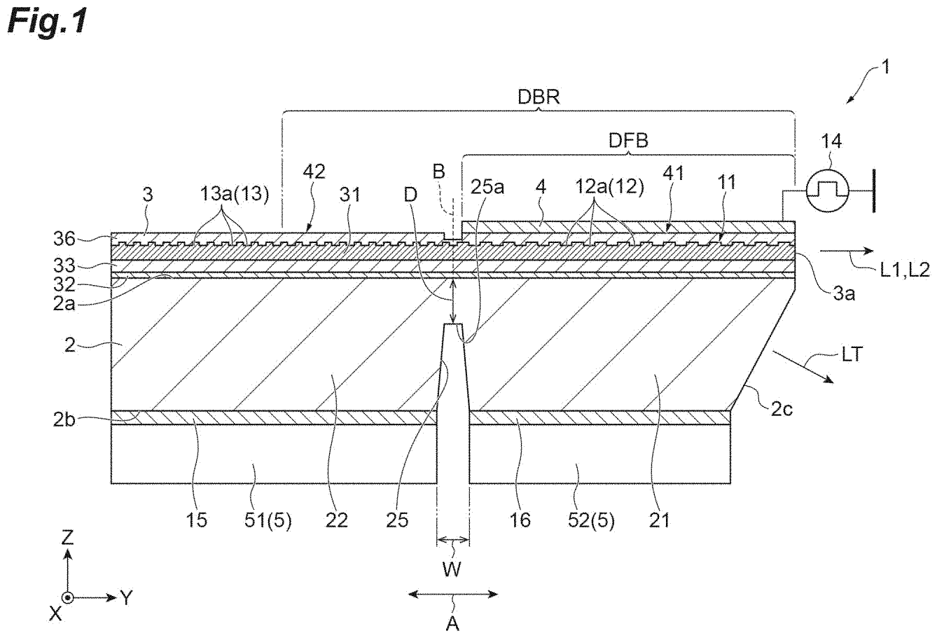

As illustrated in FIG. 1, a terahertz non-linear quantum cascade laser (hereinafter, also simply referred to as a “quantum cascade laser”) 1 includes a semiconductor substrate 2, an optical waveguide 3, and an electrode 4. The semiconductor substrate 2 is, for example, a substrate made of a single crystal of InP. In the following description, a width direction of the semiconductor substrate 2 is referred to as an X direction, a length direction of the semiconductor substrate 2 is referred to as a Y direction, and a thickness direction of the semiconductor substrate 2 is referred to as a Z direction.

The semiconductor substrate 2 has a first surface 2a, a second surface 2b opposite to the first surface 2a, and an inclined surface 2c connected to the second surface 2b. The first surface 2a and the second surface 2b are, for example, flat surfaces perpendicular to the Z direction and face each other in the Z direction. The inclined surface 2c is an end surface of the semiconductor substrate 2 in the Y direction and is a flat surface extending to be inclined with respect to the Y direction. In the quantum cascade laser 1, an output light LT is emitted from the inclined surface 2c.

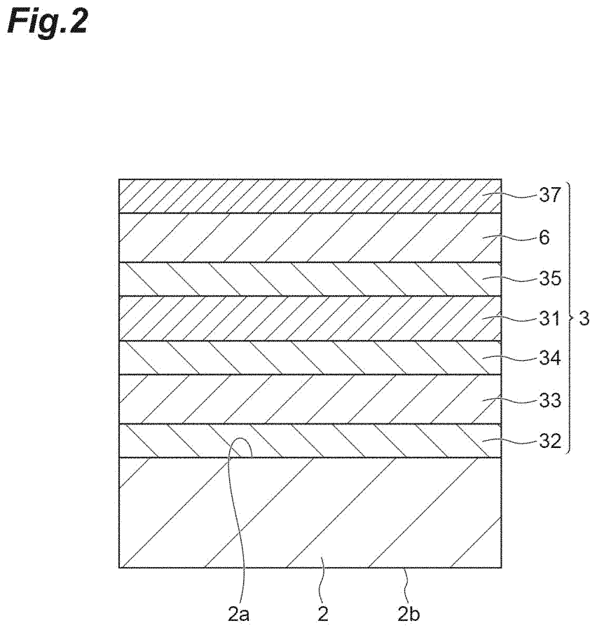

As illustrated in FIGS. 1 and 2, the optical waveguide 3 is formed on the first surface 2a of the semiconductor substrate 2. In this example, the optical waveguide 3 has a ridge portion extending along the Y direction. A width of the ridge portion in the X direction is smaller than a width of the semiconductor substrate 2 in the X direction. The optical waveguide 3 includes an active layer 31 having a quantum cascade structure. The optical waveguide 3 is configured to oscillate a laser beam having a central wavelength in a mid-infrared region. The optical waveguide direction A (direction in which light is guided in the optical waveguide 3) of the optical waveguide 3 is a direction parallel to the Y direction.

In the present embodiment, the optical waveguide 3 is configured by laminating a current diffusion layer 32, a first clad layer 33, a first guide layer 34, an active layer 31, a second guide layer 35, a second clad layer 36, and a contact layer 37 from the semiconductor substrate 2 in this order. The first clad layer 33 and the second clad layer 36 are a pair of clad layers interposing the active layer 31 therebetween. These layers 31 to 37 are formed on the semiconductor substrate 2 by crystal growth using, for example, a metal organic vapor phase epitaxy (MOVPE) method, a molecular beam epitaxy (MBE) method, or the like.

The active layer 31 includes, for example, unit laminate structures stacked in multiple stages and has a multiple quantum well structure. The multiple quantum well structure includes a plurality of well layers made of InGaAs and a plurality of barrier layers made of InAlAs. The current diffusion layer 32 is made of InGaAs and has a thickness of 250 nm. Each of the first clad layer 33 and the second clad layer 36 is made of InP and has a thickness of 5 μm. Each of the first guide layer 34 and the second guide layer 35 is made of InGaAs and has a thickness of 250 nm. The contact layer 37 is made of InGaAs and has a thickness of 250 nm.

The active layer 31 has a cascade structure in which a quantum well light emitting layer used to generate light and an electron injection layer used to inject electrons into the light emitting layer are laminated alternately and in multiple stages. Specifically, the active layer 31 having a cascade structure is configured by using a semiconductor laminated structure composed of a light emitting layer and an injection layer as the unit laminate structure for one cycle and laminating the unit laminate structures in multiple stages. The number of the unit laminate structure is appropriately set according to the specific configuration, characteristics, and the like of the laser element. By repeating electron injection and emission transition and relaxation in the unit laminate structure, cascade-like light generation occurs in the active layer 31.

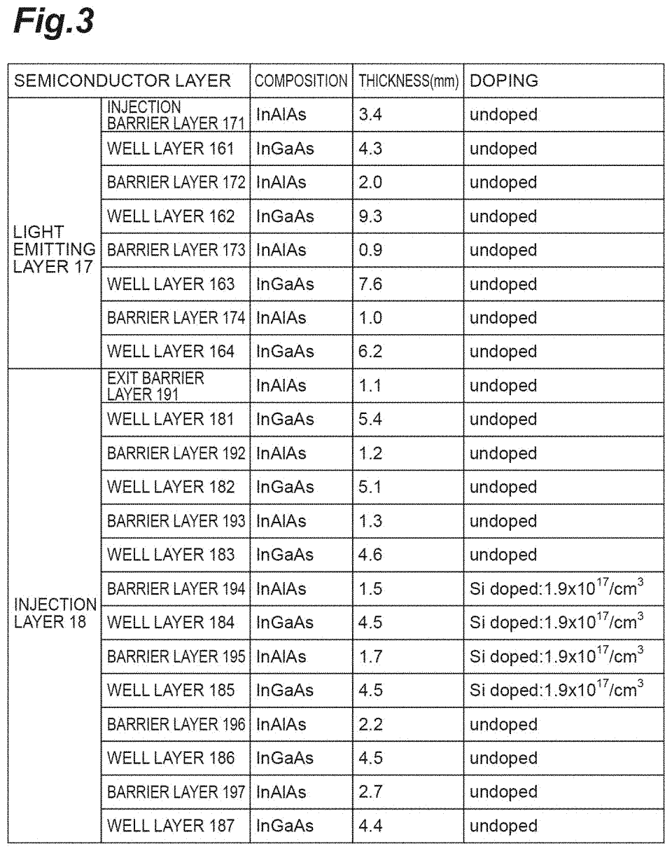

In the example illustrated in FIG. 3, the active layer 31 is configured by laminating the unit laminate structure including a quantum well light emitting layer 17 and an electron injection layer 18. The unit laminate structure for one cycle is configured as a quantum well structure in which 11 quantum well layers 161 to 164 and 181 to 187 and 11 quantum barrier layers 171 to 174 and 191 to 197 are alternately laminated. For example, the quantum well layer is configured with an InGaAs layer which is lattice-matched to the semiconductor substrate 2 made of InP, and the quantum barrier layer is configured with an InAlAs layer which is lattice-matched to the semiconductor substrate 2.

The laminated portion configured with the well layers 161 to 164 and the barrier layers 171 to 174 mainly functions as the quantum well light emitting layer 17. The laminated portion configured with the well layers 181 to 187 and the barrier layers 191 to 197 mainly functions as the electron injection layer 18. Among the semiconductor layers of the quantum well light emitting layer 17, the first-stage quantum barrier layer 171 functions as an injection barrier layer for electrons injected from the electron injection layer 18 into the quantum well light emitting layer 17. Among the semiconductor layers of the electron injection layer 18, the first-stage quantum well layer 191 functions as an exit barrier layer for electrons from the quantum well light emitting layer 17 to the electron injection layer 18. The quantum well layer 191 may not function as an exit barrier layer.

The optical waveguide 3 has a first region 41 and a second region 42. The second region 42 is located on one side (left side in FIG. 1) in the optical waveguide direction A with respect to the first region 41. The first region 41 is located on the other side (right side in FIG. 1) in the optical waveguide direction A with respect to the second region 42. The first region 41 is located on the inclined surface 2c side (emission direction side of the output light LT) with respect to the second region 42.

A diffraction grating structure 11 is provided at a boundary between the second guide layer 35 and the second clad layer 36. That is, the diffraction grating structure 11 is formed in the second guide layer 35 and the second clad layer 36, and is provided on the side opposite to the semiconductor substrate 2 with respect to the active layer 31. The diffraction grating structure 11 includes a first diffraction grating structure 12 formed in the first region 41 and a second diffraction grating structure 13 formed in the second region 42. The first diffraction grating structure 12 has a plurality of grooves 12a extending in the X direction, and the second diffraction grating structure 13 has a plurality of grooves 13a extending in the X direction. The plurality of grooves 12a and the plurality of grooves 13a are arranged in the Y direction at constant pitches (intervals). The pitches of the grooves 12a and 13a are different from each other. In this example, the pitch of the grooves 12a is set to be larger than the pitch of the grooves 13a. A boundary between the first diffraction grating structure 12 and the second diffraction grating structure 13 coincides with a boundary B between the first region 41 and the second region 42.

The electrode 4 is formed on the contact layer 37 in the first region 41. Further, electrodes (not illustrated) are also formed on the current diffusion layer 32 exposed on both sides of the ridge portion of the optical waveguide 3 in the X direction. The quantum cascade laser 1 operates by applying a bias between the electrodes.

More specifically, for example, a pulse voltage is applied to the electrode 4 by a bias application unit 14. Accordingly, the first region 41 functions as a distributed feedback (DFB) region, so that a laser beam is oscillated in the first region 41, and a first light L1 having a first wavelength λ1 corresponding to the pitch of the groove 12a of the first diffraction grating structure 12 is generated. Further, the second region 42 functions as a distributed Bragg reflector (DBR) region, so that a laser beam is oscillated in the first region 41 and the second region 42, and a second light L2 having a second wavelength λ2 corresponding to the pitch of the groove 13a of the second diffraction grating structure 13 is generated. The first light L1 and the second light L2 are emitted from the end surface 3a of the optical waveguide 3 in the optical waveguide direction A.

In the optical waveguide 3, the output light LT which is a terahertz light having a difference-frequency (|ω1−ω2|) corresponding to a difference between the first wavelength λ1 and the second wavelength λ2 due to the difference-frequency generation (DFG), which is one of the nonlinear optical effects, is generated. The frequency ω1 is a frequency corresponding to the first wavelength λ1, and the frequency ω2 is a frequency corresponding to the second wavelength λ2. As described above, the output light LT is emitted from the inclined surface 2c. The output light LT is light in the terahertz band having a wavelength of about 60 μm to 300 μm.

In the quantum cascade laser 1, Cherenkov phase matching is used to generate and output a light having a difference-frequency due to difference-frequency generation. Cherenkov phase matching is a pseudo phase matching method, in which the output light LT is radiated in a direction inclined with respect to a traveling direction (optical waveguide direction A) of a mid-infrared pump light (first light L1, second light L2). For this reason, in the quantum cascade laser 1, the output light LT is emitted from the inclined surface 2c inclined with respect to the optical waveguide direction A.

In the quantum cascade laser 1 according to the embodiment, a recess 25 for suppressing heat transfer between the first region 41 and the second region 42 is formed at the second surface 2b of the semiconductor substrate 2. In this example, the recess 25 is configured by a groove extending straight in the X direction (direction perpendicular to the optical waveguide direction A) when viewed from the Z direction (direction perpendicular to the second surface 2b). The recesses 25 reach both ends of the semiconductor substrate 2 in the X direction. The recess 25 is arranged so as to overlap the boundary B between the first region 41 and the second region 42 when viewed from the Z direction.

The recess 25 has a rectangular or trapezoidal cross section that is uniform in the X direction. The width (length in the optical waveguide direction A) W of the recess 25 is, for example, 100 μm or more and 500 μm or less. As an example, the width W may be 200 μm. The width W is a width of the recess 25 on the second surface 2b. The recess 25 is formed by, for example, scraping off the semiconductor substrate 2 with a dicing saw (dicing blade), but the recess 25 may be formed by etching or the like. The depth of the recess 25 is, for example, ½ or more of the distance (thickness of the semiconductor substrate 2 at the position of the recess 25) D between a bottom surface 25a of the recess 25 and the first surface 2a of the semiconductor substrate 2. The distance D is, for example, 100 μm or more. Accordingly, the mechanical strength of the quantum cascade laser 1 can be secured.

The quantum cascade laser 1 further includes a temperature adjusting member 5 for adjusting the temperature of the first region 41 and the temperature of the second region 42. The temperature adjusting member 5 includes a first temperature adjusting member 51 for adjusting the temperature of the second region 42 and a second temperature adjusting member 52 for adjusting the temperature of the first region 41. Each of the first temperature adjusting member 51 and the second temperature adjusting member 52 is, for example, a Peltier element. The first temperature adjusting member 51 and the second temperature adjusting member 52 are metallized for connection with solder materials 15 and 16 described later.

The first temperature adjusting member 51 and the second temperature adjusting member 52 are arranged on the second surface 2b of the semiconductor substrate 2. The second temperature adjusting member 52 is arranged on the first portion 21 of the semiconductor substrate 2, and the first temperature adjusting member 51 is arranged on the second portion 22 of the semiconductor substrate 2. The first portion 21 is a portion overlapping the first region 41 when viewed from the Z direction, and the second portion 22 is a portion overlapping the second region 42 when viewed from the Z direction. In this example, the recess 25 is located between the first portion 21 and the second portion 22. The first temperature adjusting member 51 and the second temperature adjusting member 52 are fixed to the second surface 2b by the solder materials 15 and 16 and are thermally connected to the first portion 21 and the second portion 22 via the solder materials 15 and 16, respectively.

The second temperature adjusting member 52 adjusts the temperature of the first region 41 by adjusting the temperature of the first portion 21. In other words, the second temperature adjusting member 52 adjusts the temperature of the first portion 21 and the temperature of the first region 41. The first temperature adjusting member 51 adjusts the temperature of the second region 42 by adjusting the temperature of the second portion 22. In other words, the first temperature adjusting member 51 adjusts the temperature of the second portion 22 and the temperature of the second region 42.

During the driving of the quantum cascade laser 1, while the temperature of the second region 42 is adjusted (controlled) by the first temperature adjusting member 51 and the temperature of the first region 41 is adjusted (controlled) by the second temperature adjusting member 52, a voltage is applied to the electrode 4. For example, the second region 42 is heated by the first temperature adjusting member 51, and thus, the temperature of the second region 42 is increased. Accordingly, the refractive index changes in the second region 42, and thus, the second wavelength λ2 of the second light L2 changes. Then, heat is transferred from the second region 42 and the second portion 22 to the first region 41 and the first portion 21, but the temperature of the first region 41 is maintained constant due to cooling by the second temperature adjusting member 52. That is, during the driving, the temperature of the first region 41 and the temperature of the second region 42 are adjusted so that the temperature of the first region 41 is constant and the temperature of the second region 42 is higher than the temperature of the first region 41 by the first temperature adjusting member 51 and the second temperature adjusting member 52.

When a temperature difference (temperature contrast) is formed between the first region 41 and the second region 42 in this manner, the wavelength (frequency) of the output light LT changes. Therefore, the frequency of the output light LT can be adjusted by adjusting the temperature of the first region 41 and the temperature of the second region 42 by using the first temperature adjusting member 51 and the second temperature adjusting member 52. Further, since the temperature of the second region 42 is adjusted in a state where the temperature of the first region 41 is maintained constant, the steady state of the laser is easily maintained, and the quantum cascade laser 1 can be continuously driven.

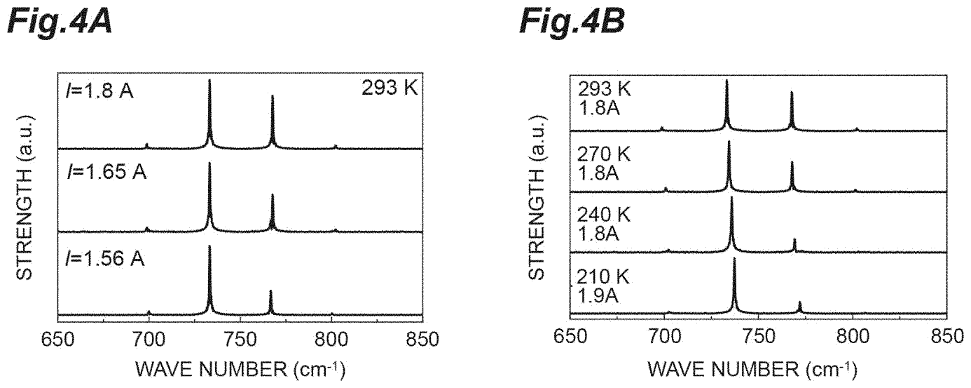

FIG. 4A is a graph illustrating changes in the first wavelength λ1 and the second wavelength λ2 when the applied current is changed while the temperature is constant, and FIG. 4B is a graph illustrating changes in the first wavelength λ1 and the second wavelength λ2 when the temperature is changed while the applied current is constant. As illustrated in FIGS. 4A and 4B, even if the magnitude of the applied current or the temperature is changed, each of the first wavelength λ1 and the second wavelength λ2 is similarly shifted, so that the frequency of the output terahertz light LT cannot be changed. In contrast, in the quantum cascade laser 1 according to the embodiment, as described above, the temperature of the first region 41 and the temperature of the second region 42 are individually adjusted by using the first temperature adjusting member 51 and the second temperature adjusting member 52, and thus, a temperature difference is formed between the first region 41 and the second region 42, so that the wavelength of the output light LT can be adjusted.

An example of a method of manufacturing the quantum cascade laser 1 is as follows. First, the optical waveguide 3 is formed on the semiconductor substrate 2 (optical waveguide forming process). In the optical waveguide forming process, the optical waveguide is formed by crystal growth so that the current diffusion layer 32, the first clad layer 33, the first guide layer 34, the active layer 31, the second guide layer 35, the second clad layer 36, and the contact layer 37 are laminated from the semiconductor substrate 2 in this order. In the optical waveguide forming process, subsequently, the ridge portion is formed on the optical waveguide 3 by Cl-based dry etching. This etching is performed so as to reach the current diffusion layer 32 via the contact layer 37, the second clad layer 36, the second guide layer 35, the active layer 31, the first guide layer 34, and the first clad layer 33. After the optical waveguide forming process, the electrode 4 is formed on the contact layer 37 remaining on the ridge portion, and the electrode is formed on the current diffusion layer 32 exposed to both sides of the ridge portion. Subsequently, the recess 25 is formed on the second surface 2b of the semiconductor substrate 2. As described above, the recess 25 is formed by using a dicing saw, but the recess 25 may be formed by etching. These processes are performed, for example, in a wafer state. After that, the wafer is cut into pieces. After that, the first temperature adjusting member 51 and the second temperature adjusting member 52 are fixed to the second surface 2b. By the above-described processes, a plurality of the quantum cascade lasers 1 can be obtained. It is noted that the optical waveguide 3 may include a burying layer formed so as to interpose the active layer 31, the first guide layer 34, and the second guide layer 35 in a width direction (X direction) of the ridge portion. The burying layer is located between the first clad layer 33 and the second clad layer 36 in the Z direction. The burying layer is, for example, an Fe-doped InP layer, and is formed by buried regrowth by MOCVD or the like.

### [Function and Effect]

In the quantum cascade laser 1, the temperature adjusting member 5 includes a first temperature adjusting member 51 for adjusting the temperature of the second region 42. Accordingly, the temperature of the second region 42 can be adjusted by using the first temperature adjusting member 51, and as a result, a temperature difference is formed between the first region 41 and the second region 42, so that the frequency of the output light LT can be changed. Further, the recess 25 (heat separation structure) for suppressing heat transfer between the first region 41 and the second region 42 is formed at the second surface 2b of the semiconductor substrate 2. Accordingly, the heat transfer from the second region 42 to the first region 41 can be suppressed, and the increase in the oscillation threshold value in the first region 41 caused by the heat transfer can be suppressed. In addition, a situation in which the first wavelength λ1 is shifted due to the heat transfer can be suppressed. Therefore, according to the quantum cascade laser 1, the increase in the oscillation threshold value can be suppressed while the frequency of the output light LT can be tuned.

The recess 25 is arranged so as to overlap the boundary B between the first region 41 and the second region 42 when viewed from the Z direction perpendicular to the second surface 2b. Accordingly, the heat transfer from the second region 42 to the first region 41 can be efficiently suppressed.

The recess 25 is a groove. Accordingly, the heat transfer from the second region 42 to the first region 41 can be efficiently suppressed.

The length of the recess 25 in the optical waveguide direction is 100 μm or more and 500 μm or less. Accordingly, the heat transfer from the second region 42 to the first region 41 can be efficiently suppressed.

The depth of the recess 25 is twice or more the distance D between the bottom surface 25a of the recess 25 and the first surface 2a. Accordingly, the heat transfer from the second region 42 to the first region 41 can be efficiently suppressed.

The first temperature adjusting member 51 is arranged on the second surface 2b of the semiconductor substrate 2. Accordingly, the temperature of the second region 42 can be adjusted via the semiconductor substrate 2 having a relatively large heat capacity, and a large temperature difference can be formed between the first region 41 and the second region 42. In particular, in the present embodiment, the temperature is adjusted from the second surface 2b side by the first temperature adjusting member 51 and the recess 25 is formed on the second surface 2b, and thus, a large temperature difference can be formed between the first region 41 and the second region 42.

The temperature adjusting member 5 further includes a second temperature adjusting member 52 for adjusting the temperature of the first region 41. Accordingly, since the temperature of the second region 42 can be adjusted by using the first temperature adjusting member 51 in a state where the temperature of the first region 41 is maintained constant by using, for example, the second temperature adjusting member 52, the steady state of the laser can be easily maintained, and as a result, continuous driving can be performed.

The second temperature adjusting member 52 is arranged on the second surface 2b of the semiconductor substrate 2. Accordingly, the temperature of the first region 41 can be adjusted via the semiconductor substrate 2 having a relatively large heat capacity, and a large temperature difference can be formed between the first region 41 and the second region 42. In particular, in the present embodiment, the temperature is adjusted from the second surface 2b side by the second temperature adjusting member 52 and the recess 25 is formed on the second surface 2b, and thus, a large temperature difference can be formed between the first region 41 and the second region 42.

The first temperature adjusting member 51 and the second temperature adjusting member 52 are Peltier elements. Accordingly, the temperature of the first region 41 and the temperature of the second region 42 can be appropriately adjusted.

The diffraction grating structure 11 includes a first diffraction grating structure 12 being formed in the first region 41 and having the grooves 12a arranged at a pitch corresponding to the first wavelength λ1 and a second diffraction grating structure 13 being formed in the second region 42 and having the grooves 13a arranged at a pitch corresponding to the second wavelength λ2. Accordingly, the first region 41 can generate the first light L1 having the first wavelength λ1, and the second region 42 can generate the second light L2 having the second wavelength λ2.

### MODIFIED EXAMPLES

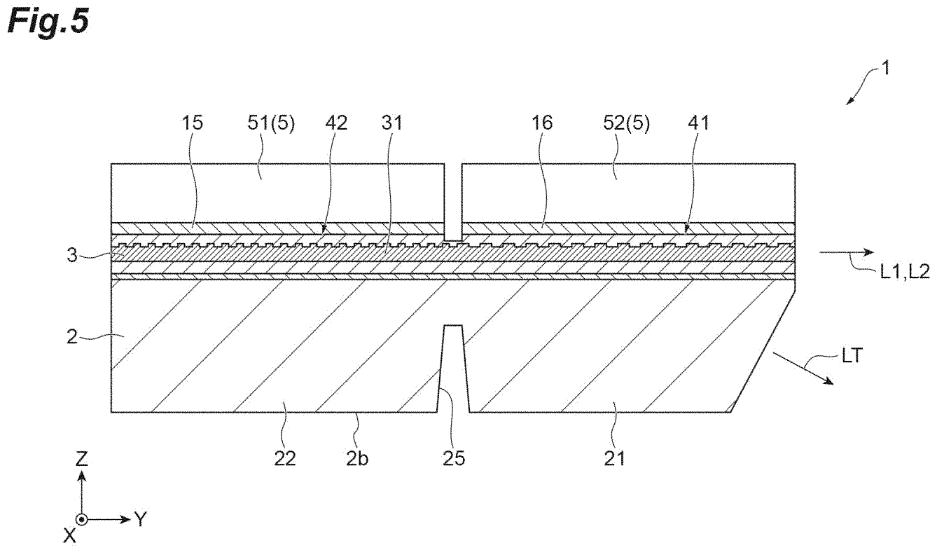

In Modified Example 1 illustrated in FIG. 5, the first temperature adjusting member 51 and the second temperature adjusting member 52 are arranged on a surface of the optical waveguide 3 opposite to the semiconductor substrate 2 via the solder materials 15 and 16. Also in Modified Example 1, similarly to the above-described embodiment, the increase in the oscillation threshold value can be suppressed while the frequency of the output light LT can be tuned. Further, since the first temperature adjusting member 51 and the second temperature adjusting member 52 are arranged on the surface of the optical waveguide 3 opposite to the semiconductor substrate 2, the first temperature adjusting member 51 and the second temperature adjusting member 51 can be close to the active layer, and thus, the temperature of the first region 41 and the temperature of the second region 42 can be adjusted with high accuracy.

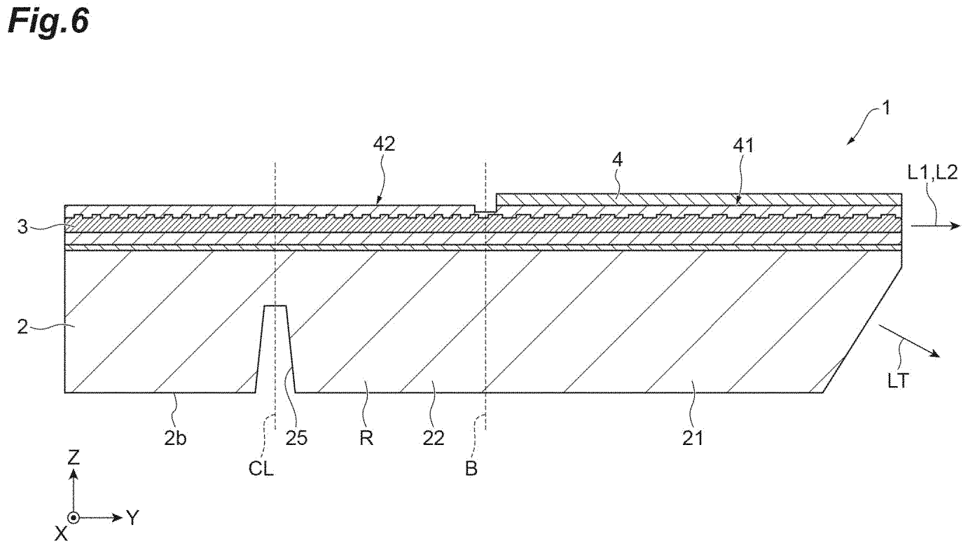

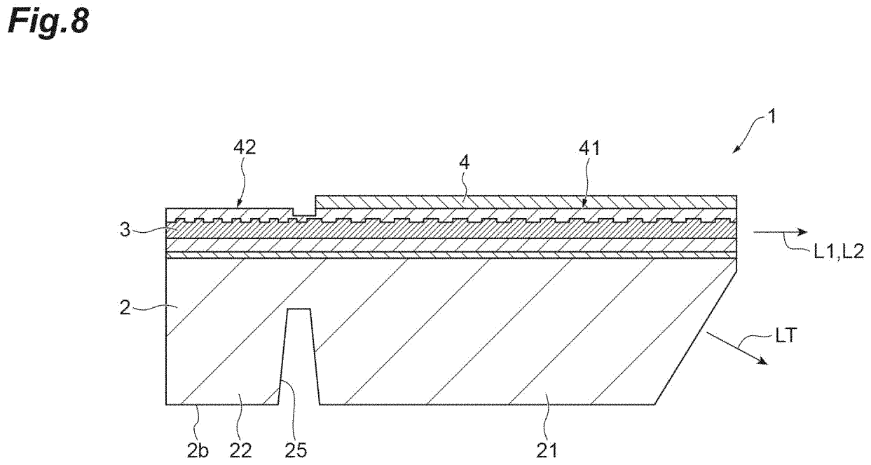

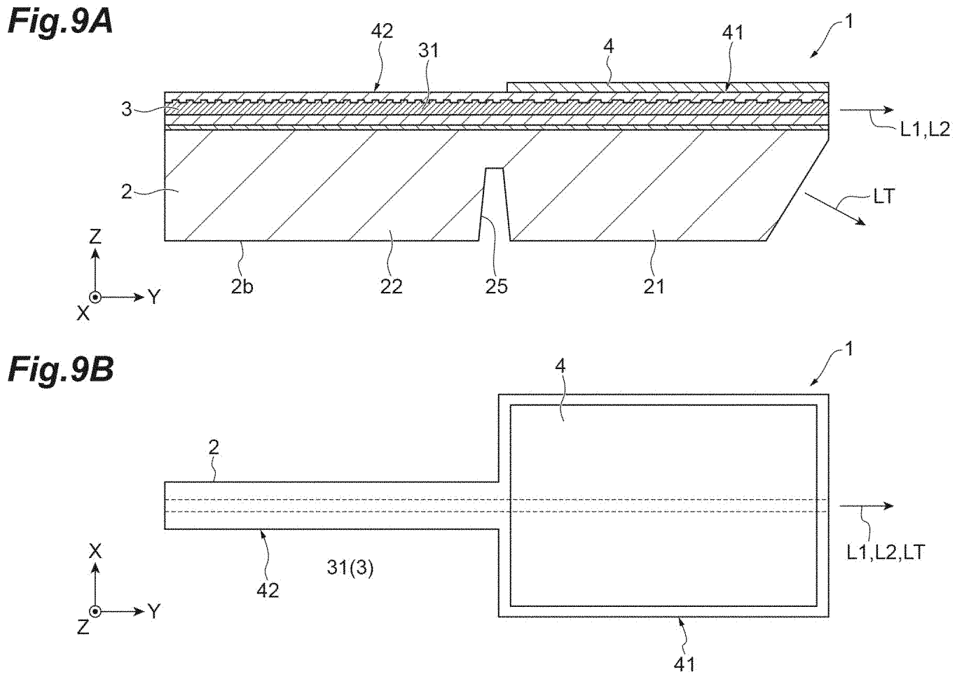

In Modified Example 2 illustrated in FIG. 6, the recess 25 is arranged so as to overlap a region R between the boundary B between the first region 41 and the second region 42 and a straight line CL bisecting the second region 42 into one side and the other side in the optical waveguide direction A when viewed from the Z direction. In this example, the recess 25 overlaps the straight line CL when viewed from the Z direction, and a portion of the recess 25 overlaps the region R. Also in Modified Example 2, similarly to the above-described embodiment, the increase in the oscillation threshold value can be suppressed while the frequency of the output light LT can be tuned. It is noted that, in FIG. 6, the temperature adjusting member 5 is omitted in illustration. This point is the same for FIGS. 8 and 9A to be described later. In Modified Example 2, the recess 25 may be arranged so that at least a portion of the recess 25 overlaps the region R when viewed from the Z direction, and the entire recess 25 may overlap the region R (the recess 25 may be arranged between the boundary B and the straight line CL). When viewed from the X direction, the center of the recess 25 is located on the second region 42 side with respect to the boundary B. The recess 25 exists only in the second region 42 and does not exist in the first region 41.

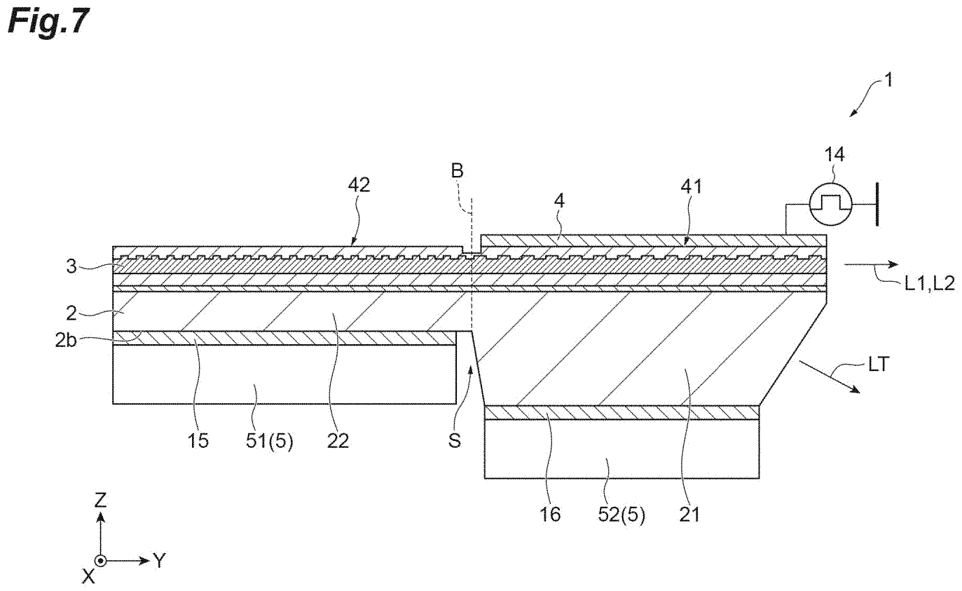

In Modified Example 3 illustrated in FIG. 7, the thickness of the first portion 21 of the semiconductor substrate 2 is larger than the thickness of the second portion 22, and thus, the heat capacity of the first portion 21 is larger than the heat capacity of the second portion 22. Since the first portion 21 is thicker than the second portion 22, a step portion S is formed between the first portion 21 and the second portion 22. The step portion S is formed at a position overlapping the boundary B in the Z direction. The semiconductor substrate 2 can be formed, for example, by thinning the second portion 22. It is noted that the thickness of the first portion 21 and the thickness of the second portion 22 are the lengths in the Z direction.

Also in Modified Example 3, similarly to the above-described embodiment, the temperature of the second region 42 can be adjusted by using the first temperature adjusting member 51, and as a result, a temperature difference is formed between the first region 41 and the second region 42, so that the frequency of the output light LT can be changed. Further, in the semiconductor substrate 2, the heat capacity of the first portion 21 is larger than the heat capacity of the second portion 22 (heat separation structure). Accordingly, even if heat is transferred from the second region 42 to the first region 41, an increase in the temperature of the first region 41 due to the heat can be suppressed, and as a result, an increase in the oscillation threshold value can be suppressed. Therefore, even with Modified Example 3, the increase in the oscillation threshold value can be suppressed while the frequency of the output light LT can be tuned. Further, in Modified Example 3, since the second portion 22 is thick, a large area of the inclined surface 2c which is the emission surface of the output light LT can be secured.

In Modified Example 4 illustrated in FIG. 8, the length of the first portion 21 in the optical waveguide direction A is larger than the length of the second portion 22 in the optical waveguide direction A, so that the heat capacity of the first portion 21 is larger than the heat capacity of the second portion 22. Similarly to Modified Example 3, in Modified Example 4, the increase in the oscillation threshold value can be suppressed while the frequency of the output light LT can be tuned. It is noted that, in Modified Example 4, the thickness and width of the first portion 21 and the thickness and width of the second portion 22 are equal to each other. Further, in Modified Example 4, the recess 25 is formed at the second surface 2b of the semiconductor substrate 2. Accordingly, the increase in the oscillation threshold value can be further suppressed.

In Modified Example 5 illustrated in FIGS. 9A and 9B, the width of the first portion 21 is larger than the width of the second portion 22, so that the heat capacity of the first portion 21 is larger than the heat capacity of the second portion 22. Similarly to Modified Example 3, also in Modified Example 5, the increase in the oscillation threshold value can be suppressed while the frequency of the output light LT can be tuned. It is noted that the width of the first portion 21 and the width of the second portion 22 are the lengths in the X direction (direction perpendicular to both the direction perpendicular to the second surface 2b of the semiconductor substrate 2 and the optical waveguide direction A). In Modified Example 5, the thickness and the length in the optical waveguide direction A of the first portion 21 and the second portion 22 are equal to each other. Further, in Modified Example 5, the recess 25 is formed at the second surface 2b of the semiconductor substrate 2. Accordingly, the increase in the oscillation threshold value can be further suppressed.

In the above-described embodiments and modified examples, the semiconductor substrate 2 is divided into a region (first portion 21) of one side and a region (second portion 22) of the other side in the optical waveguide direction A by at least one of the recess 25 and the structures for providing a difference in heat capacity between the first portion 21 and the second portion 22.

The present disclosure is not limited to the above-described embodiments and modified examples. For example, the material and shape of each component are not limited to the above-mentioned material and shape, but various materials and shapes can be adopted. The bias application unit 14 may apply a continuous wave (CW) direct current (DC) voltage instead of the pulse voltage to the electrode 4. The diffraction grating structure 11 may be formed on the contact layer 37. However, the configuration in which the diffraction grating structure 11 is formed on the second guide layer 35 and the second clad layer 36 as in the embodiment is preferable in that the diffraction grating structure 11 can be close to the active layer 31 and the feedback can be strengthened.

In the above-described embodiment, the second region 42 functions as a DBR region, but the quantum cascade laser 1 may be configured so that the second region 42 functions as a DFB region similarly to the first region 41. However, it is preferable that the second region 42 functions as a DBR region in that the design complexity can be avoided. In the above-described embodiment, the first wavelength λ1 and the second wavelength λ2 are made different by making the pitch of the grooves 12a of the first diffraction grating structure 12 different from the pitch of the grooves 13a of the second diffraction grating structure 13. However, the pitch of the grooves 12a and the pitch of the grooves 13a may be the same. In this case, for example, the first wavelength λ1 and the second wavelength λ2 can be made different by making the amounts of applied currents or the temperatures different.

The second temperature adjusting member 52 may be omitted. The first temperature adjusting member 51 may be arranged on the second surface 2b of the semiconductor substrate 2, and the second temperature adjusting member 52 may be arranged on the surface of the optical waveguide 3 opposite to the semiconductor substrate 2. Alternatively, the first temperature adjusting member 51 may be arranged on the surface of the optical waveguide 3 opposite to the semiconductor substrate 2, and the second temperature adjusting member 52 may be arranged on the second surface 2b of the semiconductor substrate 2.

The first temperature adjusting member 51 and the second temperature adjusting member 52 are not limited to the Peltier element, and the first temperature adjusting member 51 and the second temperature adjusting member 52 may be any members as long as the temperature can be adjusted. For example, the first temperature adjusting member 51 may be an electrode arranged on the second surface 2b of the semiconductor substrate 2 or on the surface of the optical waveguide 3 opposite to the semiconductor substrate 2. In this case, the temperature of the second region 42 can be adjusted by adjusting an amount of voltage (for example, DC voltage) applied to the electrode. Similarly, the second temperature adjusting member 52 may be an electrode arranged on the second surface 2b of the semiconductor substrate 2 or on the surface of the optical waveguide 3 opposite to the semiconductor substrate 2.

In the above-described embodiment, a plurality of holes may be formed as the recesses 25 on the second surface 2b of the semiconductor substrate 2. For example, the plurality of holes may be arranged along the X direction. Even in this case, similarly to the above-described embodiment, the increase in the oscillation threshold value can be suppressed while the frequency of the output light LT can be tuned. Further, since the semiconductor substrate 2 exists between the plurality of holes, the mechanical strength can be secured.

What is claimed is:

1. A quantum cascade laser comprising:
a semiconductor substrate including a first surface and a second surface opposite to the first surface;
an optical waveguide including an active layer having a quantum cascade structure and a pair of clad layers interposing the active layer therebetween, the optical waveguide being formed on the first surface of the semiconductor substrate and being provided with a diffraction grating structure; and
a temperature adjusting member,
wherein the optical waveguide includes a first region and a second region located on one side with respect to the first region in an optical waveguide direction of the optical waveguide, the first region generates a first light having a first wavelength and the second region generates a second light having a second wavelength, and the optical waveguide generates an output light having a frequency corresponding to a difference between the first wavelength and the second wavelength by difference-frequency generation,
wherein a recess for suppressing heat transfer between the first region and the second region is formed at the second surface of the semiconductor substrate, and
wherein the temperature adjusting member includes a first temperature adjusting member for adjusting the temperature of the second region.

2. The quantum cascade laser according to claim 1, wherein the recess is arranged so as to overlap a boundary between the first region and the second region when viewed from a direction perpendicular to the second surface.

3. The quantum cascade laser according to claim 1, wherein the recess is arranged so as to overlap a region between a boundary between the first region and the second region and a straight line bisecting the second region into one side and the other side in the optical waveguide direction when viewed from a direction perpendicular to the second surface.

4. The quantum cascade laser according to claim 1, wherein the recess is a groove.

5. The quantum cascade laser according to claim 1, wherein a plurality of holes each of which forms the recess are formed on the second surface.

6. The quantum cascade laser according to claim 1, wherein a length of the recess in the optical waveguide direction is 100 μm or more and 500 μm or less.

7. The quantum cascade laser according to claim 1, wherein a depth of the recess is ½ or more of a distance between a bottom surface of the recess and the first surface.

8. The quantum cascade laser according to claim 1,
wherein the semiconductor substrate includes a first portion overlapping the first region and a second portion overlapping the second region when viewed from a direction perpendicular to the second surface, and
wherein a heat capacity of the first portion is larger than a heat capacity of the second portion.

9. The quantum cascade laser according to claim 8, wherein a length of the first portion in the optical waveguide direction is larger than a length of the second portion in the optical waveguide direction.

10. The quantum cascade laser according to claim 8, wherein a width of the first portion is larger than a width of the second portion.

11. A quantum cascade laser comprising:
a semiconductor substrate including a first surface and a second surface opposite to the first surface;
an optical waveguide including an active layer having a quantum cascade structure and a pair of clad layers interposing the active layer therebetween, the optical waveguide being formed on the first surface of the semiconductor substrate and being provided with a diffraction grating structure; and
a temperature adjusting member,
wherein the optical waveguide includes a first region and a second region located on one side with respect to the first region in an optical waveguide direction of the optical waveguide, the first region generates a first light having a first wavelength and the second region generates a second light having a second wavelength, and the optical waveguide generates an output light having a frequency corresponding to a difference between the first wavelength and the second wavelength by difference-frequency generation,
wherein the semiconductor substrate includes a first portion overlapping the first region and a second portion overlapping the second region when viewed from a direction perpendicular to the second surface,
wherein a heat capacity of the first portion is larger than a heat capacity of the second portion, and
wherein the temperature adjusting member includes a first temperature adjusting member for adjusting the temperature of the second region.

12. The quantum cascade laser according to claim 11, wherein a thickness of the first portion is larger than a thickness of the second portion.

13. The quantum cascade laser according to claim 11, wherein a length of the first portion in the optical waveguide direction is larger than a length of the second portion in the optical waveguide direction.

14. The quantum cascade laser according to claim 11, wherein a width of the first portion is larger than a width of the second portion.

15. The quantum cascade laser according to claim 1, wherein the first temperature adjusting member is arranged on the second surface of the semiconductor substrate.

16. The quantum cascade laser according to claim 1, wherein the first temperature adjusting member is arranged on a surface of the optical waveguide opposite to the semiconductor substrate.

17. The quantum cascade laser according to claim 1, wherein the temperature adjusting member further includes a second temperature adjusting member for adjusting the temperature of the first region.

18. The quantum cascade laser according to claim 17, wherein the second temperature adjusting member is arranged on the second surface of the semiconductor substrate.

19. The quantum cascade laser according to claim 17, wherein the second temperature adjusting member is arranged on a surface of the optical waveguide opposite to the semiconductor substrate.

20. The quantum cascade laser according to claim 1, wherein the first temperature adjusting member is a Peltier element.

21. The quantum cascade laser according to claim 17, wherein the second temperature adjusting member is a Peltier element.

22. The quantum cascade laser according to claim 1,
wherein the diffraction grating structure includes a first diffraction grating structure formed in the first region and a second diffraction grating structure formed in the second region, and
wherein the first diffraction grating structure includes a plurality of grooves arranged at a pitch corresponding to the first wavelength, and the second diffraction grating structure includes a plurality of grooves arranged at a pitch corresponding to the second wavelength.
